(19) United States
(12) Patent Application Publication
(10) Pub. No.: US 2026/0136883 A1
(43) Pub. Date: May 14, 2026

(54) WAFER PROCESSING TOOL AND METHOD FOR PROCESSING WAFER

(71) Applicants: TSMC CHINA COMPANY LIMITED, Shanghai (CN); TAIWAN SEMICONDUCTOR MANUFACTURING COMPANY, LTD., Hsinchu (TW)

(72) Inventors: Lin MA, Shanghai City (CN); Yong Hong LUO, Shanghai City (CN); Chun LIN, Shanghai City (CN); Lei CHEN, Shanghai City (CN); Tong ZHANG, Shanghai City (CN); Jian Xin TAN, Shanghai City (CN)

(73) Assignees: TSMC CHINA COMPANY LIMITED, Shanghai (CN); TAIWAN SEMICONDUCTOR MANUFACTURING COMPANY, LTD., Hsinchu (TW)

(21) Appl. No.: 18/972,301

(22) Filed: Dec. 6, 2024

(30) Foreign Application Priority Data
Nov. 8, 2024 (CN) 202422735505.4

(51) Int. Cl. H01L 21/677; H01L 21/027; H01L 21/673

(52) U.S. Cl. CPC H10P 72/3412; H10P 72/1924; H10P 72/3402; H10P 72/3408; H10P 76/2041

(57) ABSTRACT

A method for processing a wafer is provided. The method includes forming a photoresist layer over a passivation layer on the wafer; etching an opening in the passivation layer; after etching the opening in the passivation layer, moving the wafer into a first wafer carrier, wherein the first wafer carrier has a first box and a first cover pivotally connected with the first box, and one of the first box and the first cover has an opening; and performing a first gas removal process to remove a gas released from the wafer away from the first wafer carrier through the opening.

### PRIORITY CLAIM AND CROSS-REFERENCE

This application claims priority to China Application Serial Number 202422735505.4, filed Nov. 8, 2024, which is herein incorporated by reference.

### BACKGROUND

Multiple wafers are stored and transported together in batches by a wafer carrier throughout a semiconductor fabrication facility (“fab”) between the loadports of different wafer processing tools or equipment. Such tools generally perform various photolithography, etching, material/film deposition, curing, annealing, inspection, or other processes used in IC chip manufacturing.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a schematic view of a wafer carrier according to some embodiments of the present disclosure.

FIG. 1B is an exploded schematic view of the wafer carrier of FIG. 1A.

FIG. 1C is a top view of the wafer carrier of FIG. 1A.

FIG. 1D shows a lateral side of the wafer carrier of FIG. 1A.

FIG. 1E shows a back side of the wafer carrier of FIG. 1A.

FIG. 1F is a bottom view of the wafer carrier of FIG. 1A.

FIG. 2A is a schematic view of a wafer processing tool including a rack with an exhaustion system in accordance with some embodiments of the present disclosure.

FIG. 2B illustrates plural portions of the wafer processing tool of FIG. 2A.

FIG. 3 is a flow chart of a method for processing a wafer according to some embodiments of the present disclosure.

FIGS. 4A-4G illustrate various stages of manufacture in accordance with some embodiments of the present disclosure.

FIG. 5A is a schematic view of a wafer carrier containing wafers according to some embodiments of the present disclosure.

FIG. 5B shows a top side of the wafer carrier of FIG. 5A.

FIG. 5C shows a lateral side of the wafer carrier of FIG. 5A.

FIG. 5D shows a back side of the wafer carrier of FIG. 5A.

FIG. 5E shows a bottom view of the wafer carrier of FIG. 5A.

FIG. 6A illustrates a fluorine content on a wafer surface according to some embodiments of the present disclosure.

FIG. 6B illustrates a fail rate among a plurality of wafers according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” shall generally mean within 20 percent, or within 10 percent, or within 5 percent of a given value or range. Numerical quantities given herein are approximate, meaning that the term “around,” “about,” “approximately,” or “substantially” can be inferred if not expressly stated.

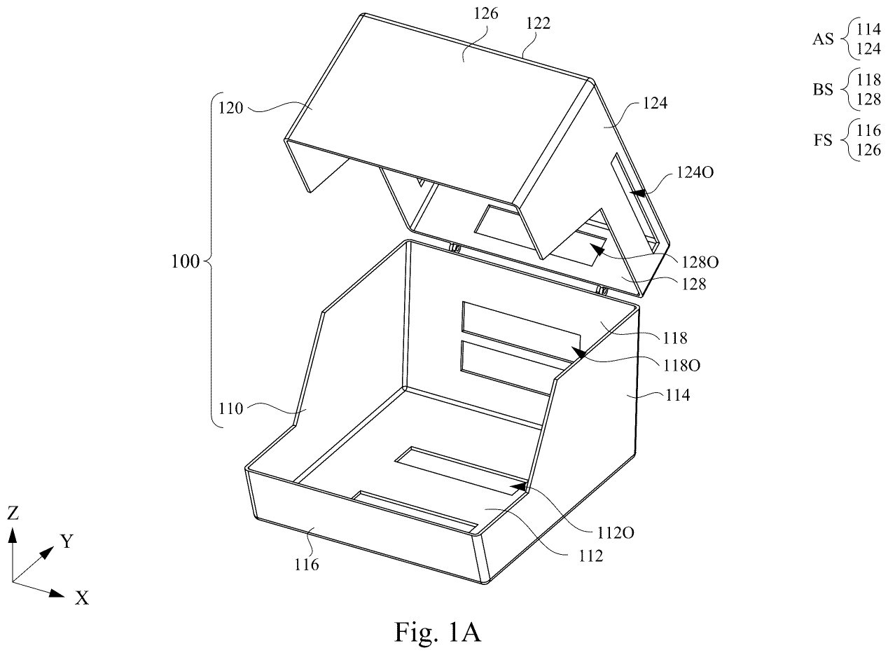

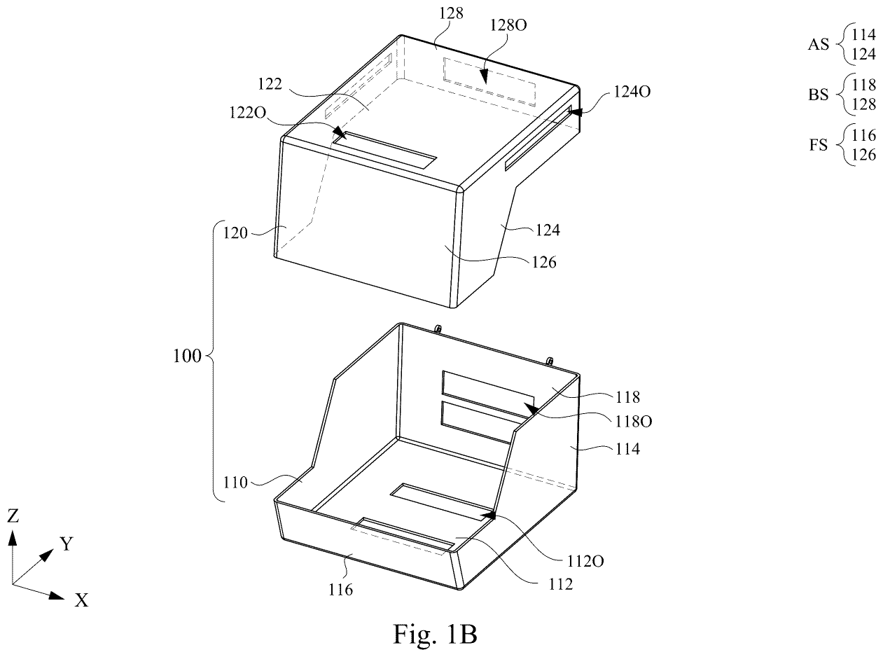

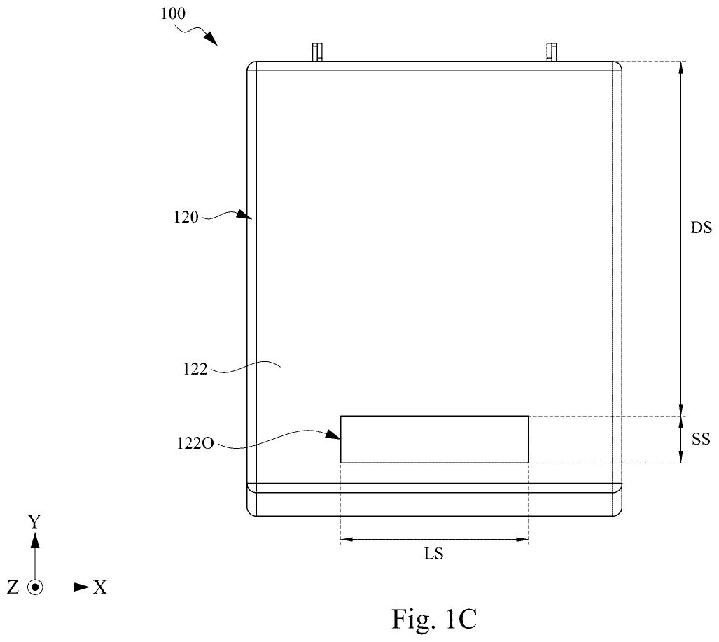

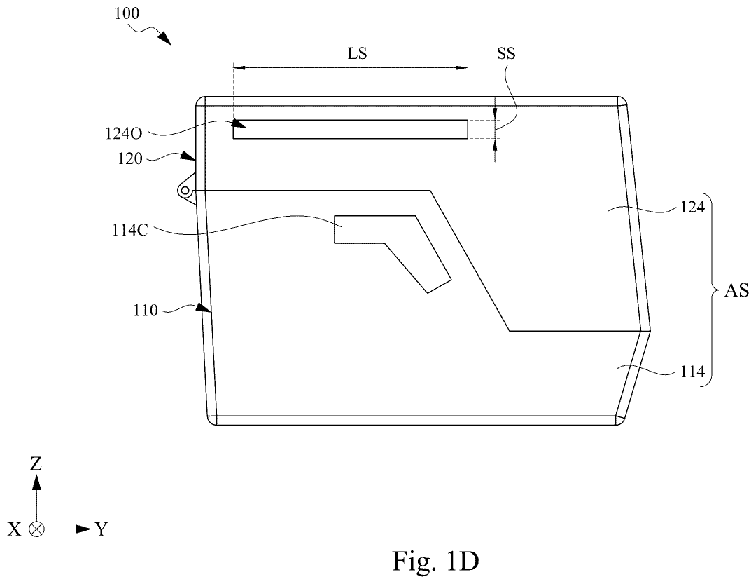

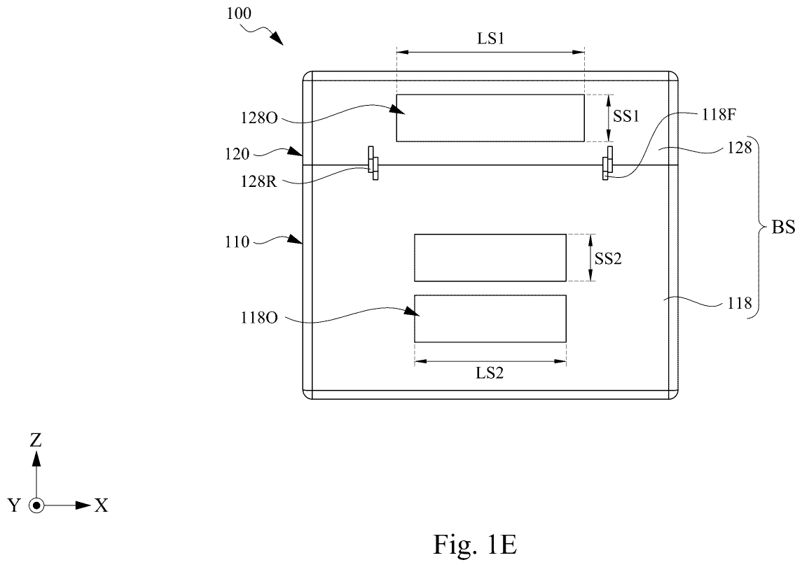

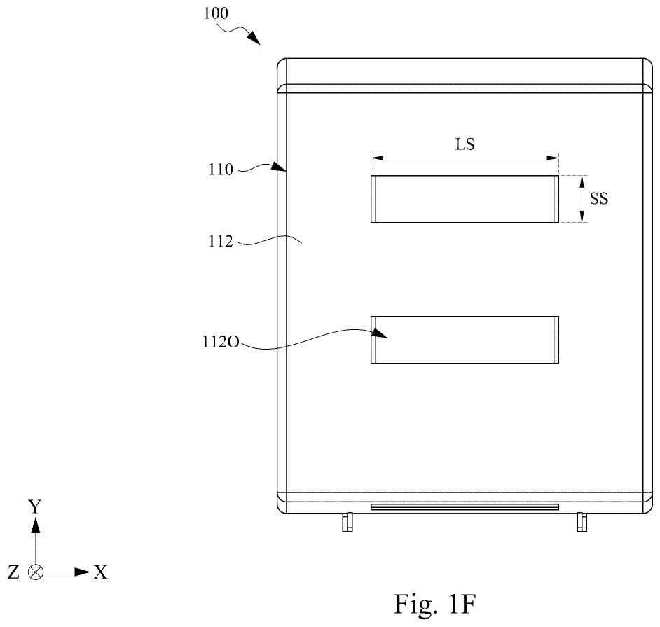

FIG. 1A is a schematic view of a wafer carrier 100 according to some embodiments of the present disclosure. FIG. 1B is an exploded schematic view of the wafer carrier 100 of FIG. 1A. The wafer carrier 100 includes a lower box 110 and an upper cover 120. The wafer carrier 100 is a box structure, and illustratively, the wafer carrier 100 includes a lower box 110 and an upper cover 120, and a space for accommodating a wafer boat is formed between the lower box 110 and the upper cover 120. The lower box 110 and the upper cover 120 may be pivotally connected by a rotating shaft. Through the configuration, the wafer carrier 100 may be opened and closed by turning over the upper cover 120. For example, the upper cover 120 can be rotated with respect to a direction X for opening or closing the wafer carrier 100. In some embodiments of the present disclosure, the lower box 110 and the upper cover 120 of the wafer carrier 100 may have one or more openings. Through the configuration, a space in the wafer carrier 100 is fluidly communicated with the environment.

The lower box 110 has a bottom box plate 112, two side box plates 114, a front box plate 116, and a back box plate 118. The upper cover 120 has a top cover plate 122, two side cover plates 124, a front cover plate 126, and a back cover plate 128. The front box plate 116 of the lower box 110 and the front cover plate 126 of the upper cover 120 can meet each other and form the front side FS of the wafer carrier 100. The back box plate 118 of the lower box 110 and the back cover plate 128 of the upper cover 120 can meet each other and form a back side BS of the wafer carrier 100. One of the side box plates 114 of the lower box 110 and one of the side cover plates 124 of the upper cover 120 can meet each other and form a lateral side AS of the wafer carrier 100, and the other one of the side box plates 114 of the lower box 110 and the other one of the side cover plates 124 of the upper cover 120 can meet each other and form another lateral side AS of the wafer carrier 100.

In some embodiments of the present disclosure, the upper cover 120 and the lower box 110 may have plural openings allowing the gas outgassing from a wafer to leave the wafer carrier 100. For example, for the upper cover 120, the top cover plate 122 may have an opening 122O, the side cover plates 124 may have openings 124O, and the back cover plate 128 may have the opening 128O. And, for the lower box 110, the bottom box plate 112 may have an opening 112O, and the back box plate 118 may have the opening 118O. The size of these openings 122O, 124O, 128O, 112O, and 118O can be determined according to the practice.

FIG. 1C is a top view of the wafer carrier 100 of FIG. 1A. The opening 122O of the top cover plate 122 may have a rectangular shape with a longitudinal direction substantially parallel with the direction X. The opening 122O may have a long side LS in a range from about 80 millimeters to about 150 millimeters, a short side SS in a range from about 20 millimeters to about 40 millimeters, and a distance DS between the opening 122O and a side far away from the opening 122O may be in a range from about 180 millimeters to about 250 millimeters.

FIG. 1D shows a lateral side AS of the wafer carrier 100 of FIG. 1A. The opening 124O of the side cover plate 124 may have a rectangular shape with a longitudinal direction substantially parallel with the direction Y. For example, the opening 124O may have a long side LS in a range from about 50 millimeters to about 200 millimeters and a short side SS in a range from about 5 millimeters to about 20 millimeters. Reference is made both to FIGS. 1A and 1D. In some embodiments, the openings 124O of the two opposite side cover plates 124 are symmetrical to each other. In some alternative embodiments, the openings 124O of the side cover plates 124 can be asymmetrical to each other. The wafer carrier 100 includes a pair of carrier handles 114C disposed on and/or fixed to the side box plate 114 of the lower box 110 for holding, moving, or carrying the wafer carrier 100 easily. The carrier handles 114C, in some embodiments, are used for manual handling of the wafer carrier 100. In the present embodiments, the side box plate 114 of the lower box 110 may not have any opening thereon. In some alternative embodiments, each of the side box plate 114 of the lower box 110 may have opening(s) thereon.

FIG. 1E shows a back side BS of the wafer carrier 100 of FIG. 1A. The back box plate 118 of the lower box 110 is pivotally connected with the back cover plate 128 of the upper cover 120, such that the wafer carrier 100 can be opened or closed by moving the lower box 110 and/or the upper cover 120. For example, the back box plate 118 of the lower box 110 may have connection elements 118F pivotally connected with connection elements 128R of the back cover plate 128 of the upper cover 120, respectively. The openings 128O of the back cover plate 128 and the openings 118O of the back box plate 118 may have a rectangular shape with a longitudinal direction substantially parallel with the direction X. For example, the opening 128O may have a long side LS1 in a range from about 80 millimeters to about 200 millimeters and a short side SS1 in a range from about 10 millimeters to about 50 millimeters. For example, the opening 118O may have a long side LS2 in a range from about 50 millimeters to about 150 millimeters and a short side SS2 in a range from about 10 millimeters to about 50 millimeters. In some embodiments, an aspect ratio of the long side LS1 and the short side SS1 of the opening 128O may be greater than an aspect ratio of the long side LS2 and the short side SS2 of the opening 118O.

FIG. 1F is a bottom view of the wafer carrier 100 of FIG. 1A. The opening 112O of the bottom box plate 112 may have a rectangular shape with a longitudinal direction substantially parallel with the direction X. For example, the opening 112O may have a long side LS in a range from about 50 millimeters to about 150 millimeters and a short side SS in a range from about 10 millimeters to about 50 millimeters.

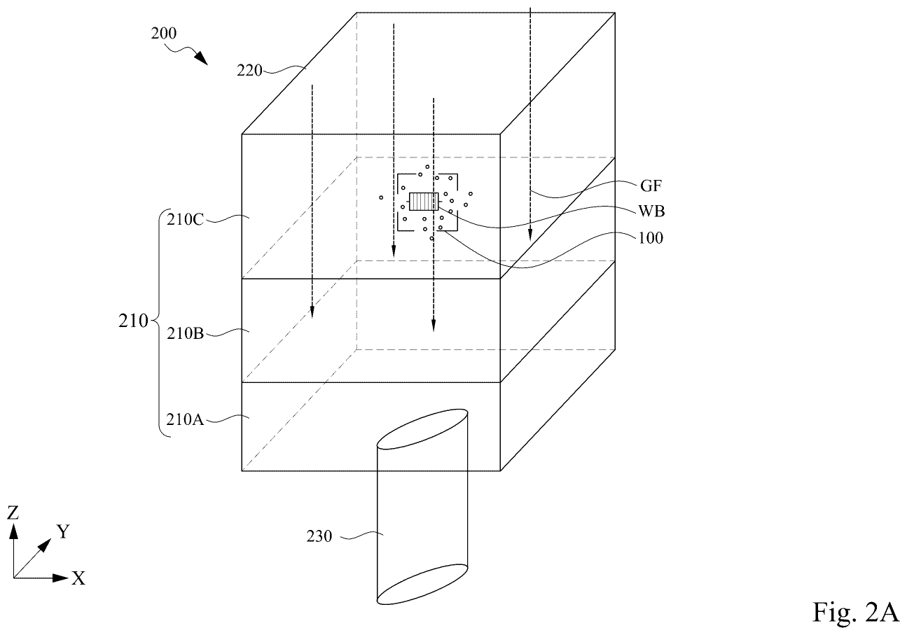

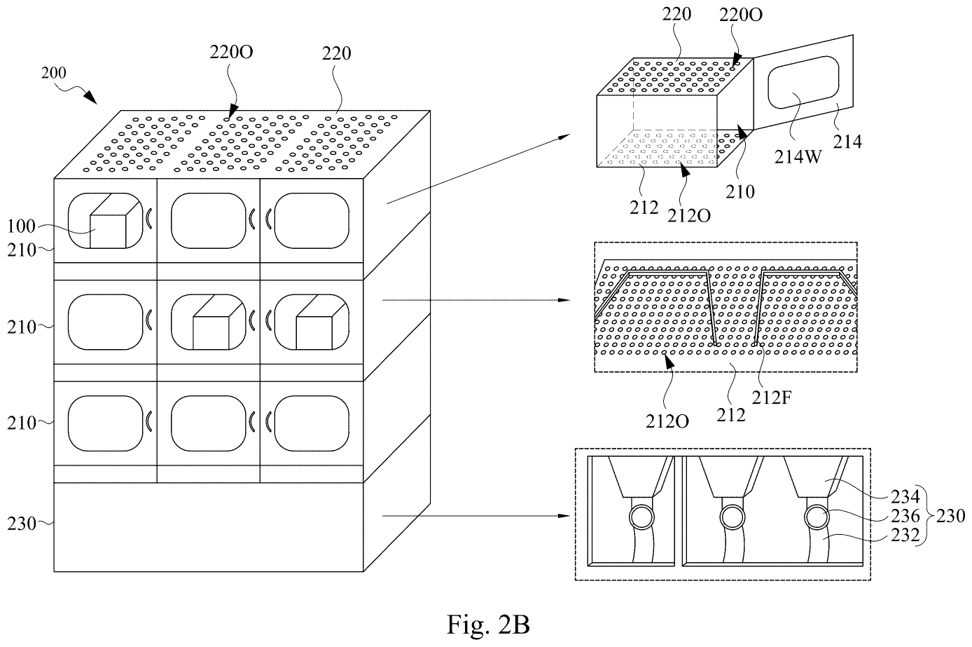

FIG. 2A is a schematic view of a wafer processing tool including a rack 200 with an exhaustion system 230 in accordance with some embodiments of the present disclosure. The rack 200 may include plural rack layers 210 one stack over another, a ceiling 220 over the rack layers 210, and an exhaustion system 230 fluidly connected to the bottommost one of the rack layers 210. One or more wafer carriers 100 and/or one or more wafer boats can be disposed in the rack layers 210 for purging the gas outgassing from wafers, for example, by the exhaustion system 230. In the context, three rack layers 210 are illustrated. In some alternative embodiments, the number of the rack layers 210 may be in a range from 1 to 10. For clear illustration, the rack layers 210 are labelled as rack layers 210A, 210B, and 210C, in which the rack layer 210B is over the rack layer 210A, and the rack layer 210C is over the rack layer 210B. The different rack layers 210A, 210B, 210C may accommodate wafer boat or wafer carrier at different steps of the process.

FIG. 2B illustrates plural portions of the wafer processing tool of FIG. 2A. Each of the rack layers 210 may have a floor 212 and plural doors 214. The floor 212 of each of the rack layers 210, where the wafer boat or the wafer carrier is put, may have plural floor openings 212O allowing the fluid communication among the rack layers 210. And, a floor 212 of the bottommost one of the rack layers 210 may have plural floor openings 212O allowing the fluid communication between the exhaustion system 230 and the bottommost one of the rack layers 210. In some embodiments, the floors 212 have positioning elements 212F configured to locate the wafer carrier/boat at a target region. The doors 214 can be open or closed for moving the wafer carrier/boat into the rack layer 210 or out of the rack layer 210. The doors 214 may have transparent windows 214W such that operators can observe the wafer carrier/boat through the transparent windows 214W without opening the doors 214. The ceiling 220 may have plural ceiling openings 220O to allow fluid communication between the topmost one of the rack layers 210 and the environment. The exhaustion system 230 may include plural exhaust pipes 232, plural exhaust funnels 234, and plural valves 236 coupled with the exhaust pipes 232. The exhaust pipes 232 may be connected with a pump. The exhaust funnels 234 are respectively connecting the exhaust pipes 232 to the bottommost one of the rack layers 210. Through the configuration, by operating the exhaustion system 230, a continuous downward gas flow GF (shown in FIG. 2A) is generated from the environment, through the ceiling 220 (e.g., through the ceiling openings 220O) and the rack layers 210 (e.g., through the floor opening 212O), and to the exhaustion system 230. The continuous downward gas flow GF (shown in FIG. 2A) is generated without considering the movement of the wafer boat or the wafer carrier. Combining the rack 200 with the wafer carriers 100, it is effectively to remove the fluorine-containing gas outgassing from the wafer, thereby reducing the fluorine-containing gas around the wafer. The configuration of the exhaust funnels 234 enlarge a cross-section area that the gas flow GF passes through. In the illustrated embodiments, the exhaustion system 230 is connected to a bottom of the rack layer 210. In some alternative embodiments, the exhaustion system 230 may be connected to other portions of the rack layer 210 for providing better airflow to remove the outgassing.

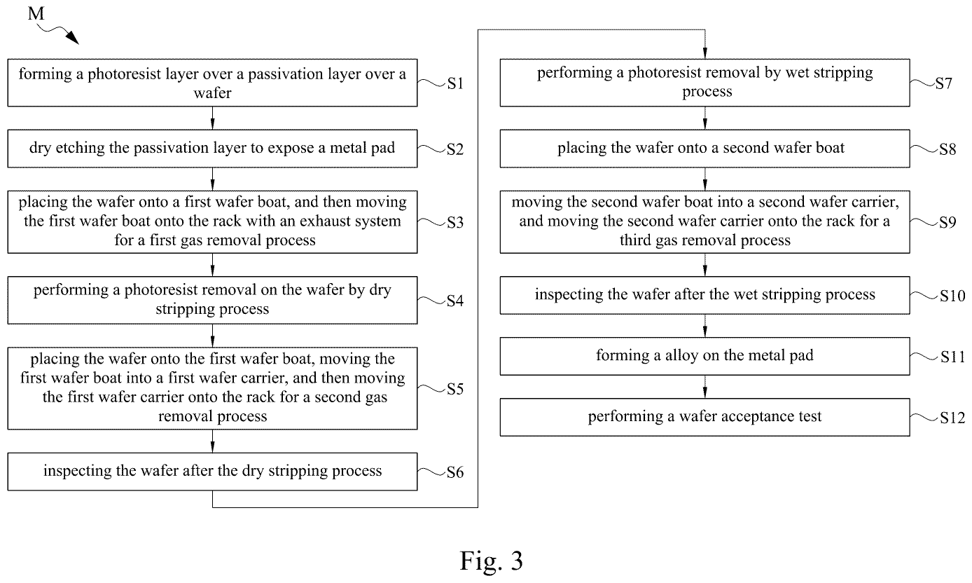

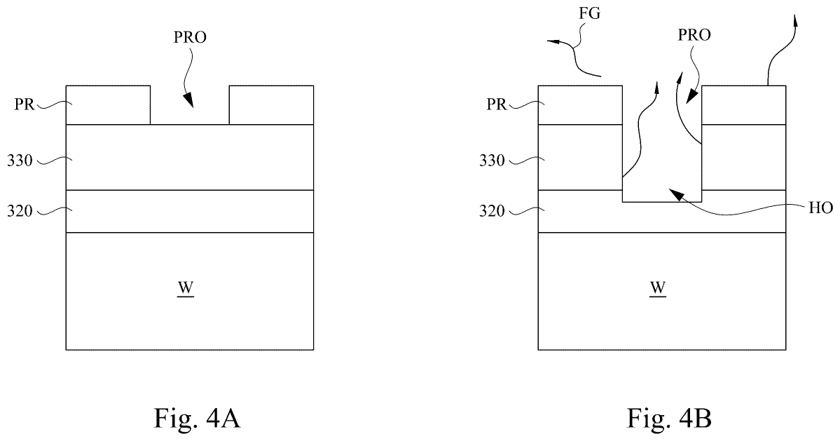

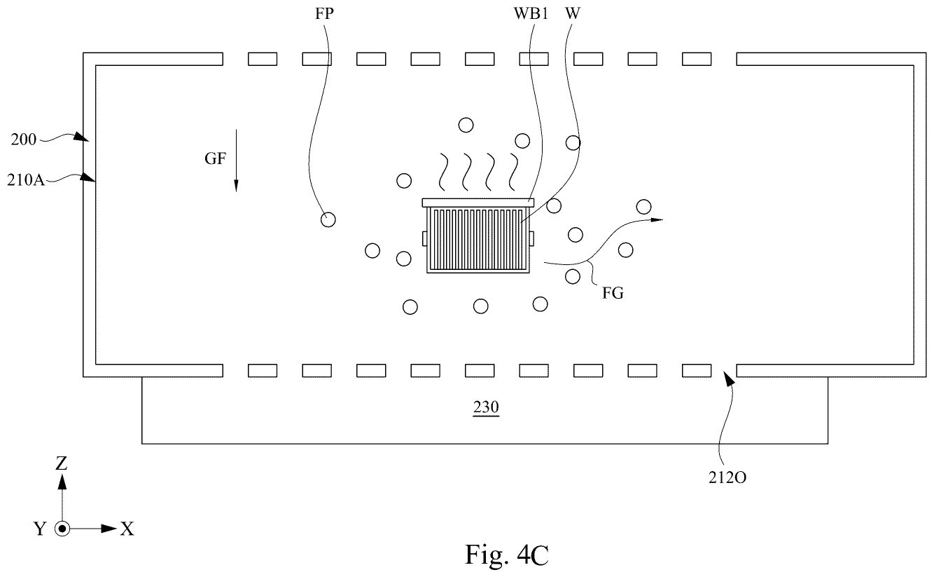

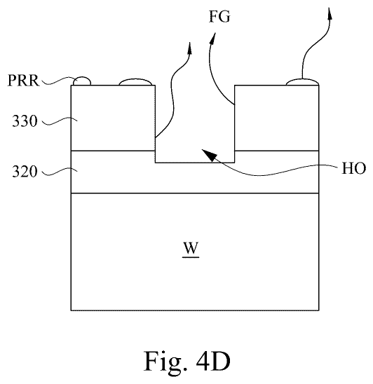

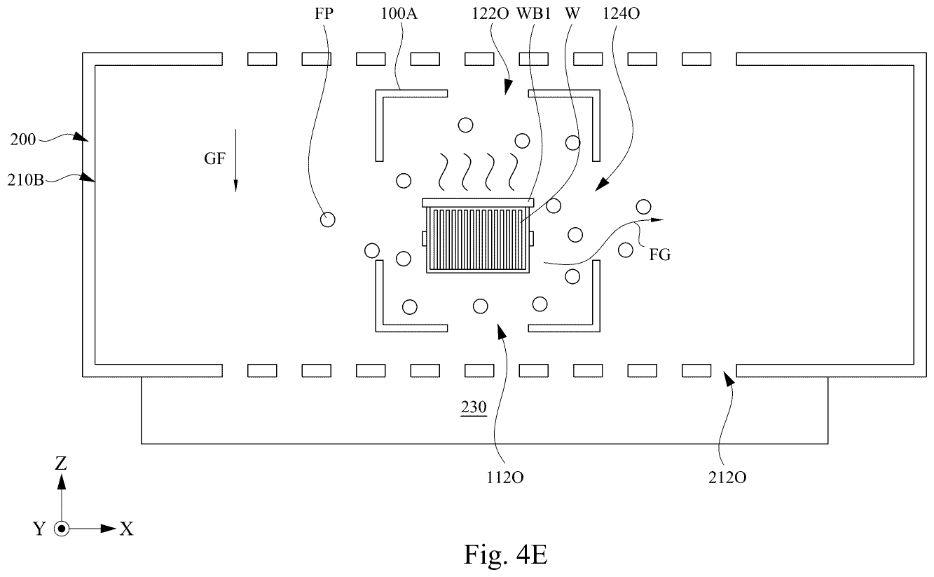

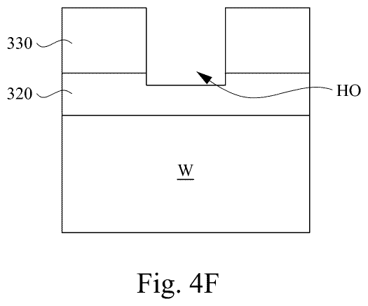

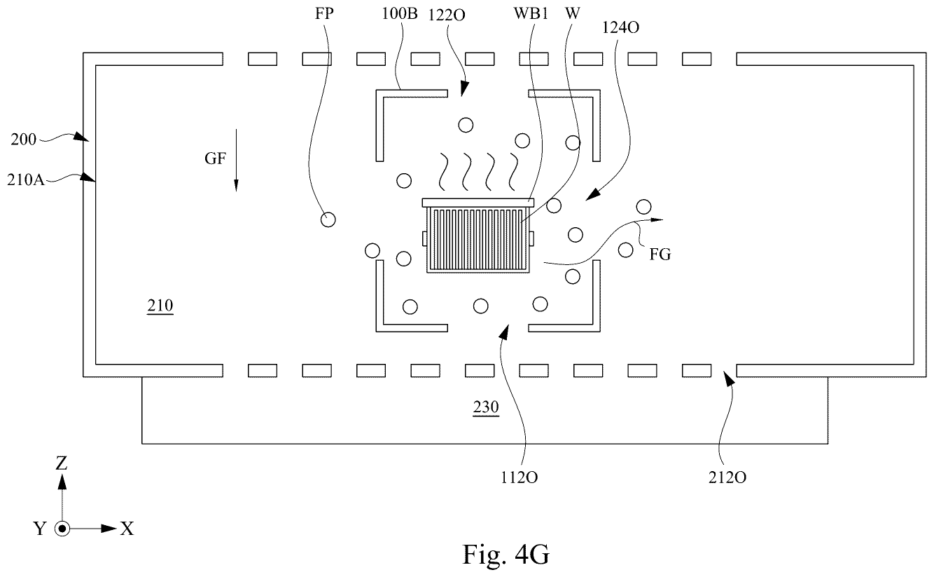

FIG. 3 is a flow chart of a method M for processing a wafer according to some embodiments of the present disclosure. FIGS. 4A-4G illustrate various stages of manufacture in accordance with some embodiments of the present disclosure. The method M may include steps S1-S12. At step S1, a photoresist layer is formed over a passivation layer over a wafer. At step S2, the passivation layer is, for example, dry etched to expose a metal pad. At step S3, the wafer is placed onto a first wafer boat, and then the first wafer boat is moved onto the rack with an exhaust system for a first gas removal process. At step S4, a photoresist removal is performed on the wafer by, for example, dry stripping process. At step S5, the wafer is placed onto the first wafer boat, the first wafer boat is moved into a first wafer carrier, and then the first wafer carrier is moved onto the rack for a second gas removal process. At step S6, the wafer is inspected after the dry stripping process. At step S7, a photoresist removal is performed by a wet stripping process, for example. At step S8, the wafer is placed onto a second wafer boat. At step S9, the second wafer boat is moved into a second wafer carrier, and the second wafer carrier is moved onto the rack for a third gas removal process. At step S10, the wafer is inspected after the wet stripping process. At step S11, an alloy on the metal pad is formed. At step S12, a wafer acceptance test is performed. It is understood that additional steps may be provided before, during, and after the steps S1-S12 shown in FIG. 3, and some of the steps described below can be replaced or eliminated for additional embodiments of the method. The order of the operations/processes may be interchangeable.

Reference is made to FIG. 3 and FIG. 4A. The method M begins at step S1, where a photoresist layer PR is formed over a passivation layer 330 over a wafer W. The wafer W may be referred to as a semiconductor substrate. The wafer W may be made of a suitable elemental semiconductor, such as silicon, diamond or germanium; a suitable alloy or compound semiconductor, such as Group-IV compound semiconductors (silicon germanium (SiGe), silicon carbide (SiC), silicon germanium carbide (SiGeC), GeSn, SiSn, SiGeSn), Group III-V compound semiconductors (e.g., gallium arsenide (GaAs), indium gallium arsenide (InGaAs), indium arsenide (InAs), indium phosphide (InP), indium antimonide (InSb), gallium arsenic phosphide (GaAsP), or gallium indium phosphide (GaInP)), or the like. Further, the wafer W may include an epitaxial layer (epi-layer), which may be strained for performance enhancement, and/or may include a silicon-on-insulator (SOI) structure.

In some embodiments, one or more active and/or passive devices are formed on the wafer W. An interconnect structure may be formed over the active and/or passive devices. The interconnect structure may include a metallization pattern comprising metal lines extending horizontally and metal vias extending vertically in dielectric layers. Then, one or more metal pads 320 (also referred to as a top metal layer) are then formed over the interconnect structure to be in direct contact with the underlying metallization pattern in the interconnect structure. Thus, the metal pads 320 are electrically connected the underlying metallization pattern in the interconnect structure. The metal pads 320 may be formed of aluminum, aluminum copper, aluminum alloys, copper, copper alloys, or the like. For example, the metal pad 320 includes AlCu pad. The metal pads 320 may also be referred to as bond pads. The passivation layer 330 is formed to cover the metal pads 320. The passivation layer 330 may be formed of a dielectric material, such as undoped silicate glass (USG), silicon nitride, silicon oxide, silicon oxynitride or a non-porous material by any suitable method, such as CVD, PVD, or the like. The passivation layer 330 may be a single layer or a laminated layer. It is noted that a single layer of metal pads 320 and a passivation layer 330 are shown for illustrative purposes only. As such, other embodiments may include any number of metal pads and/or passivation layers.

The photoresist layer PR is formed over the passivation layer 330 by a photolithography process, for example. The photolithography processes may include photoresist coating (e.g., spin-on coating), soft baking, mask aligning, exposure, post-exposure baking, developing the photoresist, rinsing, drying (e.g., hard baking), and/or other applicable processes. The photoresist layer PR has an opening PRO exposing the underlying passivation layer 330.

Reference is made to FIG. 3 and FIG. 4B. The method M proceeds to step S2, where the passivation layer 330 is etched to expose a metal pad 320. In the present embodiments, a dry etch process (e.g., using a fluorine-containing gas) is performed using the photoresist layer PR as an etch mask, such that a first portion of the passivation layer 330 exposed by the opening PRO of the photoresist layer PR is removed by being etched, and a second portion of the passivation layer 330 covered by the photoresist layer PR is protected from being etched. As a result, an opening HO is etched in the passivation layer 330 according to the profile and location of the opening PRO of the photoresist layer PR. In some embodiments, the metal pad 320 is slightly consumed by the dry etch process, such that a top surface of a first portion of the metal pad 320 exposed by the opening HO is lower than a top surface of a second portion of the metal pad 320 covered by the passivation layer 330.

In some embodiments, the dry etch process for etching the passivation layer 330 uses a fluorine-containing gas, such as SF₆, CF₄, CHF₃, the like, or the combination thereof. After the dry etch process is completed, fluoride will remain in the sidewall polymer, photoresist layer PR, and the metal pad 320, and the fluoride may outgas from the wafer W. For example, the fluorine-containing gas FG with fluorine particles FP (shown in FIG. 4C) is released from the wafer W. In absence of effectively removing the fluorine-containing gas FG outgassing from the wafer W, a reaction between the fluorine-containing gas FG and exposed AlCu metal pad 320 after the passivation etching process can occur. Crystals may grow on passivation window, thereby forming the pad defects before the packaging. The pad defects may cause bonding failure and reduce the wafer reliability. Sometimes, the pad defects may cause wafer scrapping and reduce manufacture yield rate. The chemical formula regarding the reaction between the fluorine-containing gas FG and exposed AlCu metal pad 320 is exemplarily illustrated as below:

$$\begin{matrix}Al + {xF}^{-} \to {[ {AlF}_{x} ]}^{( x - 3 ) -} + 3 {e}^{-} \\ {2 [ {AlF}_{x} ]}^{( x - 3 - )} + 4 Al + 6 {H}_{2} O \to {Al}_{x} {O}_{y} {F}_{z} .\end{matrix}$$

The x, y, and z are positive integers. The longer the reaction time, the more serious the pad defect.

Reference is made to FIG. 3 and FIG. 4C. The method M proceeds to step S3, where the wafer W is moved/placed onto a first wafer boat WB1, and then the first wafer boat WB1 is moved/placed onto the rack 200 for a first gas removal process. The first wafer boat WB1 may comprises plural slots/fixtures for holding plural wafers W and spacing the wafers W from each other. In some embodiments, the first wafer boat WB1 assumes an angle with respect to the horizontal so that wafers W are induced to rest on their respective rear surfaces and the front or upper surfaces of the wafers W are not in contact with anything. The wafer boat WB1 does not substantially enclose the wafers W. As a result, when the first wafer boat WB1 is moved/placed onto the rack 200, the wafers W are exposed to the space in the rack 200 which is fluid communicated with the environment and the exhaustion system 230. The first wafer boat WB1 may include tags revealing identities of the wafers W, and can be used at various stages of the process. The first wafer boat WB1 may also be referred to as a wafer cassette.

In some embodiments of the present disclosure, by moving/placing the wafer boat WB1 onto the rack 200 with the exhaustion system 230, the first gas removal process is performed, in which the exhaustion system 230 can effectively remove the fluorine-containing gas FG with fluorine particles FP that is released from the wafer W. Thus, the generation of crystals on the passivation window can be inhibited. As a result, the pad defects can be reduced. In the present embodiments, the wafers W stand substantially along the direction Z on the wafer boat WB1, and the gas flow GF generated by the exhaustion system 230 flows substantially along the direction Z. With this configuration, the gas flow GF can flow across the plural wafers W in a more uniform manner. In the illustrated embodiments, the first wafer boat WB1 is moved onto a rack layer 210A of the rack 200.

Reference is made to FIG. 4D. The method M proceeds to step S4, where a photoresist removal is performed on the wafer W by dry stripping process. The photoresist layer PR (referring to FIG. 4C) is removed by a dry stripping process, using a suitable gas, such as N₂, O₂, the like, or the combination thereof. Prior to the photoresist removal, the first wafer boat WB1 is moved away from the rack 200 (referring to FIG. 4C), and then the wafer W is moved from the first wafer boat WB1 (referring to FIG. 4C) to a chamber for the dry stripping process (i.e., the photoresist removal). After the photoresist removal, photoresist residues PRR, which are residues of the photoresist layer PR (referring to FIG. 4C), may remain on the wafer W. And, the fluoride may still remain in the sidewall polymer, photoresist residues PRR, and the metal pad 320, and the fluorine-containing gas FG may outgas from the wafer W. Since the using of the rack 200 at step S3 (referring to FIG. 4C), the amount of the fluorine-containing gas FG outgassing from the wafer W at this step is less than the amount of the fluorine-containing gas FG outgassing from the wafer W at the step S2 (referring to FIG. 4B).

Reference is made to FIG. 4E. The method M proceeds to step S5, where the wafer W is placed onto the first wafer boat WB1, the first wafer boat WB1 is moved/placed into a first wafer carrier 100A, and then the first wafer carrier 100A is moved/placed onto the rack 200 for a second gas removal process. In the illustrated embodiments, the first wafer carrier 100A is moved onto a rack layer 210B of the rack 200. At this step, a space of the first wafer carrier 100A is fluidly communicated with a space of the rack layer 210B through the openings 122O, 124O, and 112O of the first wafer carrier 100A (and the openings 118O and 128O of the first wafer carrier 100A, as shown in FIG. 1B).

In some embodiments of the present disclosure, by moving/placing the first wafer carrier 100A onto the rack 200 with the exhaustion system 230, the second gas removal process is performed, in which the exhaustion system 230 can effectively remove the fluorine-containing gas FG with fluorine particles FP that is released from the wafer W. Thus, the generation of crystals on the passivation window can be inhibited. As a result, the pad defects can be reduced. In the present embodiments, the wafers W stand substantially along the direction Z in the wafer carrier 100A, and the gas flow GF generated by the exhaustion system 230 flows substantially along the direction Z. With this configuration, the gas flow GF can flow across the plural wafers W in a more uniform manner.

After the step S4 (i.e., the photoresist removal using the dry stripping process) and step S5, the method M may proceed to step S6, where the wafers W are inspected for checking a condition of the photoresist residues PRR and the passivation layer 330 after the dry stripping process. In some embodiments, prior to the inspection process, the first wafer carrier 100A is moved away from the rack 200 (referring to FIG. 4E), the first wafer boat WB1 is moved away from the first wafer carrier 100A (referring to FIG. 4E), and then the wafer W is moved from the first wafer boat WB1 (referring to FIG. 4E) to a chamber for the inspection process.

Reference is made to FIG. 4F. The method M proceeds to step S7, where a photoresist removal is performed on the wafer W after the inspection process at step S6. The photoresist residues PRR (referring to FIG. 4D) are removed by a wet stripping process, using a suitable gas, such as NH₂OH, H₂O, the like, or the combination thereof. After the wet stripping process, a trivial amount of the fluoride may remain in the metal pad 320. Since the using of the rack 200 at step S5 (referring to FIG. 4E), the amount of the fluorine-containing gas outgassing from the wafer at this step is less than the amount of the fluorine-containing gas outgassing from the wafer W at the step S4 (referring to FIG. 4D).

In some embodiments, the inspection process at step S6 may be omitted/skipped. In such embodiments, prior to the photoresist removal, the first wafer carrier 100A is moved away from the rack 200 (referring to FIG. 4E), the first wafer boat WB1 is moved away from the first wafer carrier 100A (referring to FIG. 4E), and then the wafer W is moved from the first wafer boat WB1 (referring to FIG. 4E) to a chamber for the wet stripping process (i.e., the photoresist removal).

Reference is made to FIG. 4G. The method M proceeds to step S8, where the wafers W are moved/placed onto a second wafer boat WB2. In this step, the wafers W are transported to the second wafer boat WB2 different from the first wafer boat WB1 (referring to FIG. 4E) used in previous steps. The use of the second wafer boat WB2 may prevent contaminations on the first wafer boat WB1 (referring to FIG. 4E) from being brought to the subsequent process.

Subsequently, the method M proceeds to step S9, where the second wafer boat WB2 is moved/placed into a second wafer carrier 100B, and then the second wafer carrier 100B is moved/placed onto the rack 200 for a third gas removal process. In some embodiments of the present disclosure, by moving/placing the second wafer carrier 100B onto the rack 200 with the exhaustion system 230, the third gas removal process is performed, in which the exhaustion system 230 can effectively remove the fluorine-containing gas FG with fluorine particles FP that is released from the wafer W. Thus, the generation of crystals on the passivation window can be inhibited. As a result, the pad defects can be reduced. In the illustrated embodiments, the second wafer carrier 100B is moved onto a rack layer 210C of the rack 200. At this step, a space of the second wafer carrier 100B is fluidly communicated with a space of the rack layer 210C through the openings 122O, 124O, and 112O of the second wafer carrier 100B (and the openings 118O and 128O of the second wafer carrier 100B, as shown in FIG. 1B). In the present embodiments, the wafers W stand substantially along the direction Z in the wafer carrier 100B, and the gas flow GF generated by the exhaustion system 230 flows substantially along the direction Z. With this configuration, the gas flow GF can flow across the plural wafers W in a more uniform manner.

Subsequently, the method M proceeds to step S10, where the wafers W are inspected for checking a condition of the photoresist and the passivation layer 330 after the wet stripping process. In some embodiments, prior to the inspection process, the second wafer carrier 100B is moved away from the rack 200 (referring to FIG. 4G), the second wafer boat WB2 is moved away from the second wafer carrier 100B (referring to FIG. 4G), and then the wafer W is moved from the second wafer boat WB2 (referring to FIG. 4G) to a chamber for the inspection process.

After the inspection process, the method M may proceed to step S11, where an alloy may be formed on the metal pad 320 exposed by the passivation layer 330. In some alternative embodiments, the step S11 (the formation of the alloy) may be skipped or omitted. The method M may then proceed to step S12, where a wafer acceptance test (WAT) is performed. By means of the WAT, the quality and the stability of the wafers are somewhat ensured.

In some embodiments, referring to FIGS. 2A, 4C, 4E, and 4G, the steps S3, S5, and S9 may use different rack layers 210A, 210B, and 210C of the same rack 200. For example, at the step S3, the first wafer boat WB1 is moved/placed onto a first rack layer 210A of the rack 200; at step S5, the first wafer carrier 100A is moved/placed onto a second rack layer 210B of the rack 200; at step S9, the second wafer carrier 100B is moved/placed onto a third rack layer 210C of the rack 200. Stated differently, the different rack layers 210A, 210B, 210C may accommodate wafer boat or wafer carrier at different steps of the method M. In some alternative embodiments, the steps S3, S5, and S9 use different racks 200. In some alternative embodiments, the steps S3, S5, and S9 use a same rack layer 210 of the same rack 200 (e.g., one of the rack layers 210A, 210B, and 210C of the same rack 200).

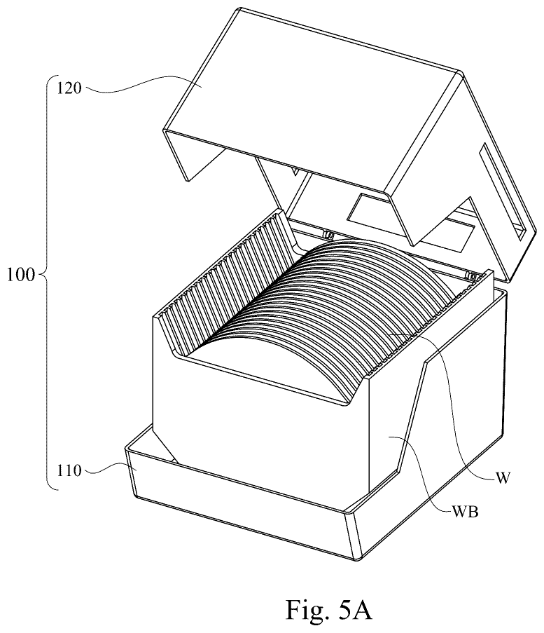

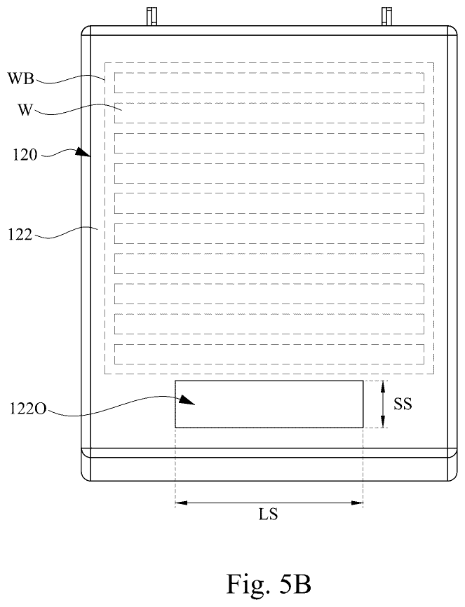

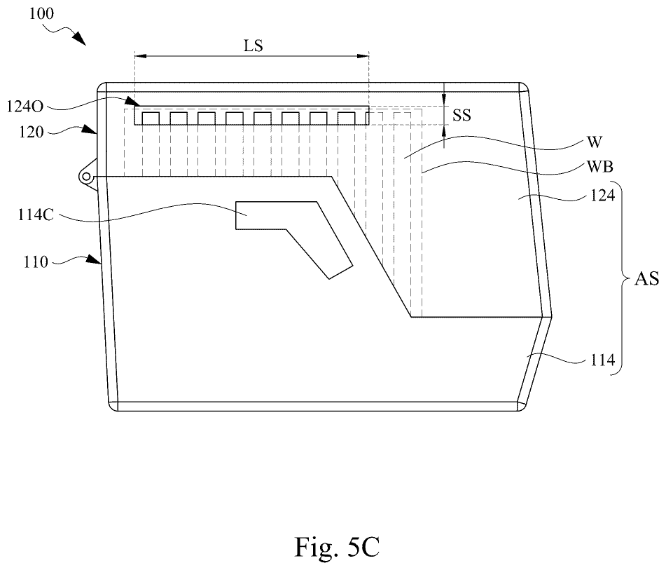

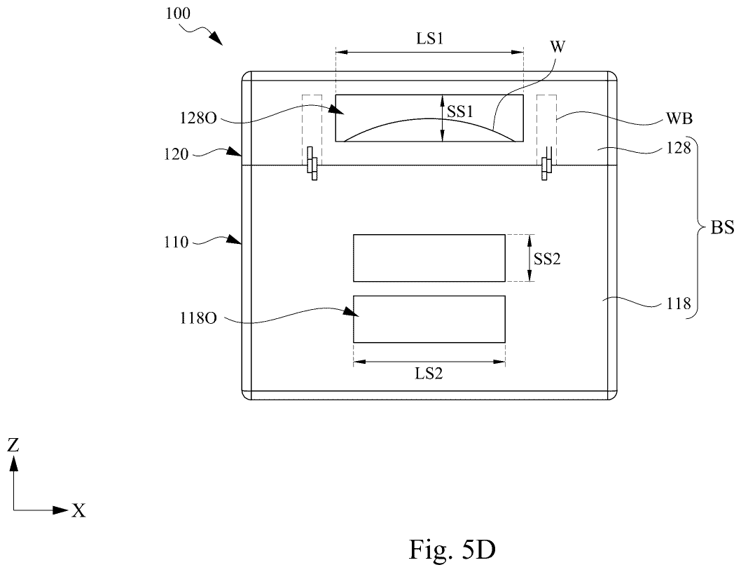

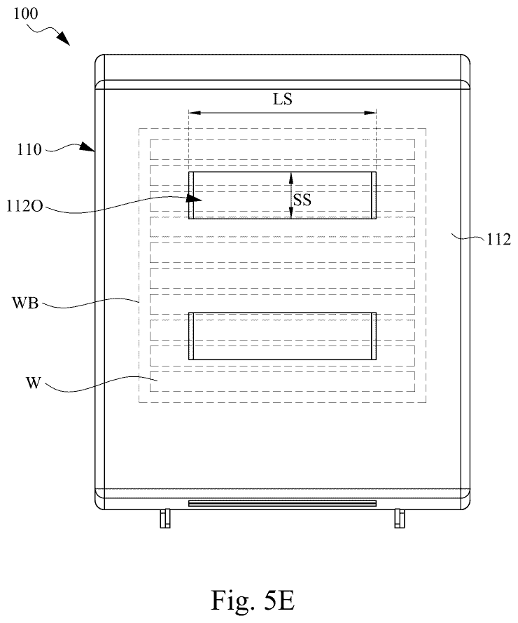

FIG. 5A is a schematic view of a wafer carrier 100 containing wafers W according to some embodiments of the present disclosure. FIG. 5B is a top view of the wafer carrier 100 of FIG. 5A. When viewed from top, the opening 122O of the top cover plate 122 is misaligned with the wafers W in the wafer carrier 100. For example, the opening 122O of the top cover plate 122 is offset from a center of the top cover plate 122. As shown in FIG. 5A, the opening 122O of the top cover plate 122 may not expose the wafer boat WB carrying the wafers W. Through the configuration, particles from environment are prevented from falling onto the wafers W in the wafer carrier 100. The opening 122O of the top cover plate 122 has a longitudinal direction substantially parallel with a direction (e.g., the direction X) which is substantially parallel the surfaces of the wafers W. In some embodiments, the long side LS of the opening 122O is less than a diameter of the wafers W. The number of the wafers W supported by the wafer boat WB2 and placed in the second wafer carrier 100B is merely exemplarily shown in the drawings and can vary according to various conditions.

FIG. 5C shows a lateral side AS of the wafer carrier 100 of FIG. 5A. The wafers W may be arranged vertically in the wafer carrier 100. The openings 124O of the two opposite side cover plates 124 may expose a portion of the wafer boat WB and edge portions of the wafers W, thereby facilitating the removing the fluorine-containing outgassing from the wafers W. In some embodiments, the long side LS of the opening 124O is much greater than a thickness of the wafers W, such that plural edge portions of the plural wafers W can be exposed by the opening 124O.

FIG. 5D shows a back side BS of the wafer carrier 100 of FIG. 5A. The wafers W may be arranged vertically in the wafer carrier 100. The openings 118O and 128O may expose portions of the wafers W, thereby facilitating the removing the fluorine-containing gas outgassing from the wafers W. The opening 128O of the back cover plate 128 and/or the opening 118O of the back box plate 118 may have a longitudinal direction substantially parallel with a direction (e.g., the direction X). In some embodiments, the long side LS1 of the opening 128O is less than a diameter of the wafers W. In some embodiments, the long sides LS2 of the openings 118O are less than a diameter of the wafers W. The number of the wafers W supported by the wafer boat WB2 and placed in the second wafer carrier 100B is merely exemplarily shown in the drawings and can vary according to various conditions.

FIG. 5E shows a bottom view of the wafer carrier 100 of FIG. 5A. The wafers W may be arranged vertically in the wafer carrier 100. The openings 112O may expose the wafers W, thereby facilitating the removing the fluorine-containing gas outgassing from the wafers W. For example, the openings 112O overlap the region of the wafer boat WB.

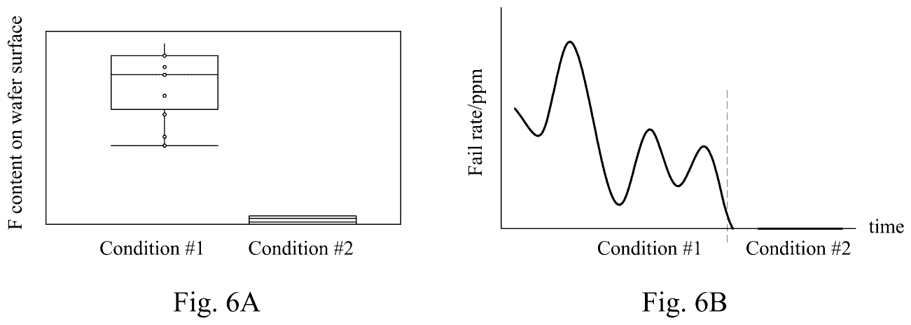

FIG. 6A illustrates a fluorine content on a wafer surface according to some embodiments of the present disclosure. The vertical axis represents a fluorine content on a wafer surface. Condition #1 indicates a fluorine content on a wafer surface of a wafer W before implementing de-gas function, for example, in absence of using the wafer carrier 100 of FIGS. 1A-1F and the rack 200 of FIGS. 2A and 2B during the process. Condition #2 indicates a fluorine content on a wafer surface of a wafer W after implementing de-gas function, for example, using the wafer carrier 100 of FIGS. 1A-1F and the rack 200 of FIGS. 2A and 2B during the process.

Comparing Condition #2 with Condition #1, the fluorine content of Condition #2 is much lower than the fluorine content of Condition #1. This indicates that implementing the de-gas function (e.g., using the wafer carrier 100 of FIGS. 1A-1F and/or the rack 200 of FIGS. 2A and 2B during the process) can obviously lower the fluorine content on the wafer surface.

FIG. 6B illustrate a fail rate among a plurality of wafers according to some embodiments of the present disclosure. The vertical axis represents a fail rate on a wafer surface parts per million (ppm). The horizontal axis indicates the timing when the de-gas function is implemented, Condition #1 indicates the timing before implementing de-gas function, and Condition #2 indicates the timing after implementing de-gas function.

Comparing Condition #2 with Condition #1, the fail rate of Condition #2 is much lower than the fail rate of Condition #1. This indicates that implementing the de-gas function (e.g., using the wafer carrier 100 of FIGS. 1A-IF and/or the rack 200 of FIGS. 2A and 2B during the process) can obviously lower the fail rate.

Based on the above discussions, it can be seen that embodiments of the present disclosure offers advantages. It is understood, however, that other embodiments may offer additional advantages, and not all advantages are necessarily disclosed herein, and that no particular advantage is required for all embodiments. One advantage is that the wafer carrier is designed with openings allowing the fluorine-containing gas to be stripped from the wafer and escape to other places, thereby preventing the fluorine-containing gas from the exposed AlCu, which in turn will reduce the formation of pad defect. Another advantage is that the shape and the size of the openings of the wafer carrier can be adjusted and determined for optimizing the production steps according to the practice. Still another advantage is that a rack is designed with rack layers having plural holes and an exhaustion system fluidly connected to the rack layers, which is beneficial for removing the fluorine-containing gas outgassing from the wafer.

According to some embodiments of the present disclosure, a method for processing a wafer is provided. The method includes forming a photoresist layer over a passivation layer on the wafer; etching a layer opening in the passivation layer; after etching the layer opening in the passivation layer, moving the wafer into a first wafer carrier, wherein the first wafer carrier has a first box and a first cover pivotally connected with the first box, and one of the first box and the first cover has an opening; and performing a first gas removal process to remove a gas released from the wafer away from the first wafer carrier through the opening of said one of the first box and the first cover.

According to some embodiments of the present disclosure, a method for processing a wafer is provided. The method includes moving a wafer into a wafer carrier, wherein the wafer stands substantially along a vertical direction in the wafer carrier, and the wafer carrier has at least one opening; moving the wafer carrier onto a rack layer of a rack, wherein a space of the wafer carrier is fluidly communicated with a space of the rack layer through the opening of the wafer carrier; and using an exhaustion system, generating a gas flow in the rack layer of the rack substantially along the vertical direction.

According to some embodiments of the present disclosure, a wafer processing tool includes a wafer carrier. The wafer carrier comprises a box and a cover over the box. The box is configured to hold a wafer boat. The box includes a bottom box plate, and the bottom box plate has a first opening. The cover includes a top cover plate spaced apart from the bottom box plate along a vertical direction, and the top cover plate has a second opening, and the second opening of the top cover plate is not aligned with the wafer boat along the vertical direction.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for processing a wafer, comprising:
forming a photoresist layer over a passivation layer on the wafer;
etching a layer opening in the passivation layer;
after etching the layer opening in the passivation layer, moving the wafer into a first wafer carrier, wherein the first wafer carrier has a first box and a first cover pivotally connected with the first box, and one of the first box and the first cover has an opening; and
performing a first gas removal process to remove a gas released from the wafer away from the first wafer carrier through the opening of said one of the first box and the first cover.

2. The method of claim 1, wherein the first gas removal process uses an exhaust system to guide the gas from the first wafer carrier.

3. The method of claim 1, wherein the first gas removal process comprises:
moving the first wafer carrier onto a rack layer; and
using an exhaust system, guiding the gas away from the rack layer.

4. The method of claim 1, further comprising:
after etching the layer opening in the passivation layer and prior to moving the wafer into the first wafer carrier, performing a dry stripping process to remove the photoresist layer from the passivation layer.

5. The method of claim 1, further comprising:
after the first gas removal process, performing a wet stripping process to remove the photoresist layer from the passivation layer.

6. The method of claim 5, further comprising:
after etching the layer opening in the passivation layer, moving the wafer into a second wafer carrier, wherein the second wafer carrier has a second box and a second cover pivotally connected with the second box, and one of the second box and the second cover has an opening; and
after the wet stripping process, performing a second gas removal process to remove the gas released from the wafer away from the second wafer carrier through the opening of said one of the second box and the second cover.

7. The method of claim 6, wherein the second gas removal process comprises:
moving the second wafer carrier onto a rack layer; and
using an exhaust system, guiding the gas away from the rack layer.

8. The method of claim 1, wherein etching the layer opening in the passivation layer is performed such that the layer opening in the passivation layer exposes a metal pad on the wafer.

9. A method for processing a wafer, comprising:
moving a wafer into a wafer carrier, wherein the wafer stands substantially along a vertical direction in the wafer carrier, and the wafer carrier has at least one opening;
moving the wafer carrier onto a rack layer of a rack, wherein a space of the wafer carrier is fluidly communicated with a space of the rack layer through the at least one opening of the wafer carrier; and
using an exhaustion system, generating a gas flow in the rack layer of the rack substantially along the vertical direction.

10. The method of claim 9, wherein the wafer carrier is moved onto the rack layer of the rack when the gas flow is generated.

11. The method of claim 9, wherein the wafer is over the opening of the wafer carrier after moving the wafer into the wafer carrier.

12. The method of claim 11, wherein the opening of the wafer carrier is aligned with the wafer along the vertical direction.

13. The method of claim 9, wherein the wafer is below the opening of the wafer carrier after moving the wafer into the wafer carrier.

14. The method of claim 13, wherein the opening of the wafer carrier is misaligned with the wafer along the vertical direction.

15. The method of claim 9, wherein moving the wafer into the wafer carrier comprises:
placing the wafer onto a wafer boat; and
moving the wafer boat into the wafer carrier.

16. A wafer processing tool, comprising:
a wafer carrier, comprising:
a box configured to hold a wafer boat, wherein the box comprises a bottom box plate, and the bottom box plate has a first opening; and
a cover over the box, wherein the cover comprises a top cover plate spaced apart from the bottom box plate along a vertical direction, the top cover plate has a second opening, and the second opening of the top cover plate is misaligned with the wafer boat along the vertical direction.

17. The wafer processing tool of claim 16, wherein the second opening of the top cover plate is misaligned with the first opening of the bottom box plate along the vertical direction.

18. The wafer processing tool of claim 16, wherein the cover comprises a side cover plate extending from the top cover plate toward the box, and the side cover plate comprises a third opening.

19. The wafer processing tool of claim 16, further comprising:
a rack comprising a plurality of rack layers, wherein each of the rack layers has a floor having a plurality of floor openings, and one of the rack layers is configured to accommodate the wafer carrier; and
an exhaustion system connected with a bottommost one of the rack layers and configured to generate a gas flow among the rack layers through the floor openings.

20. The wafer processing tool of claim 19, wherein the rack comprises a ceiling over a topmost one of the rack layers, and the ceiling has a plurality of ceiling openings.
